(19) United States
(12) Patent Application Publication
(10) Pub. No.: US 2010/0118580 A1
(43) Pub. Date: May 13, 2010

(54) SEMICONDUCTOR MEMORY DEVICE

(76) Inventors: Kang-Seol Lee, Gyeonggi-do (KR); Young-Jun Ku, Gyeonggi-do (KR)

Correspondence Address: IP & T Law Firm PLC, 7700 Little River Turnpike, Suite 207, Annandale, VA, 22003, US

(21) Appl. No.: 12/345,822

(22) Filed: Dec. 30, 2008

(30) Foreign Application Priority Data
Nov. 10, 2008 (KR) 10-2008-0111168

(51) Int. Cl. G11C 5/02; G11C 7/00

(52) U.S. Cl. 365/51; 365/189.011

(57) ABSTRACT

A semiconductor memory device includes first positive and negative data lines driven with voltage levels contrary to each other in response to first data and second positive and negative data lines driven with voltage levels contrary to each other in response to second data, wherein one of the second positive and negative data lines is disposed between the first positive and negative data lines.

### CROSS-REFERENCE TO RELATED APPLICATIONS

The present invention claims priority of Korean patent application number 10-2008-0111168, filed on Nov. 10, 2008, which is incorporated by reference in its entirety.

### BACKGROUND OF THE INVENTION

The present invention relates to semiconductor design technology, and more particularly, to a semiconductor memory device including a plurality of data lines for transmitting a plurality of data.

In general, a semiconductor memory device such as a double data rate synchronous dynamic random access memory (DDR SDRAM) device includes more than dozens of millions of memory cells to store data and stores or outputs the data in response to commands from a central processing unit (CPU). That is, if the CPU requires a write operation, the semiconductor memory device stores data in memory cells corresponding to addresses inputted from the CPU. On the other hand, if the CPU requires a read operation, the semiconductor memory device reads out data stored in memory cells corresponding to addresses inputted from the CPU. In other words, in the write operation, data provided from the external are inputted to memory cells through input/output (I/O) pads and a data input path and, in the read operation, data stored in memory cells are outputted to the external through a data output path and the I/O pads.

FIG. 1 is a view provided to explain read and write operations of a typical semiconductor memory device. Although the semiconductor memory device includes more than dozens of millions of memory cells therein, FIG. 1 shows only one memory cell for the simplicity of explanation. Herein, the memory cell is represented by a reference numeral ‘110’.

Hereinafter, the read operation of the semiconductor memory device will be described with reference to FIG. 1.

First of all, if a selected word line WL is activated through the decoding of row addresses inputted to the semiconductor memory device in response to an external command signal, a cell transistor T1 of the memory cell 110 is turned on and thus data stored in a cell capacitor C1 of the memory cell 110 is charge-shared to a pair of bit lines BL and /BL that was precharged. The positive bit line BL and the negative bit line /BL become to have a minute potential difference therebetween through the charge sharing operation.

Then, a bit line sense amplifier 120 senses and amplifies the minute potential difference between the positive bit line BL and the negative bit line /BL. In other words, in case the potential of the positive bit line BL is higher than that of the negative bit line /BL, the positive bit line BL is amplified to a pull-up supply voltage RTO and the negative bit line /BL is amplified to a pull-down supply voltage SB. Adversely, in case the potential of the positive bit line BL is lower than that of the negative bit line /BL, the positive bit line BL is amplified to the pull-down supply voltage SB and the negative bit line /BL is amplified to the pull-up supply voltage RTO.

In the meantime, if a selected column selection signal YI is enabled through the decoding of column addresses inputted to the semiconductor memory device in response to an external command signal, a column selection unit 130 is activated and thus the positive and the negative bit lines BL and /BL are connected with positive and negative segment input/output lines SIO and /SIO, respectively. That is, the amplified data on the positive bit line BL is transmitted onto the positive segment input/output line SIO and the amplified data on the negative bit line /BL is transmitted onto the negative segment input/output line /SIO.

Subsequently, if an input/output switching unit 140 is activated in response to an input/output control signal CRT_IO corresponding to the column addresses, the positive and the negative segment input/output lines SIO and /SIO are connected with positive and negative local input/output lines LIO and /LIO, respectively. That is, the data transmitted onto the positive segment input/output line SIO is transmitted onto the positive local input/output line LIO and the data transmitted onto the negative segment input/output line /SIO is transmitted onto the negative local input/output line /LIO. A read driving unit 150 drives a global input/output line GIO according to the data transmitted through the positive and the negative local input/output lines LIO and /LIO.

After all, the data stored in the memory cell 110 is transmitted onto the positive and the negative segment input/output lines SIO and /SIO via the positive and the negative bit lines BL and /BL in response to the column selection signal YI. The data transmitted onto the positive and the negative segment input/output lines SIO and /SIO is transmitted onto the positive and the negative local input/output lines LIO and /LIO in response to the input/output control signal CTR_IO. The data transmitted onto the positive and the negative local input/output lines LIO and /LIO is transmitted onto the global input/output line GIO by the read driving unit 150. The data transmitted through the above path is finally outputted to the external through a corresponding I/O pad (not shown).

Meanwhile, in the write operation, data provided from the external is transmitted in the opposite direction to that of the reading operation. Namely, the data inputted through the I/O pad is transmitted from the global input/output line GIO to the positive and the negative local input/output lines LIO and /LIO through a write driving unit 160. Then, the data transmitted onto the positive and the negative local input/output lines LIO and /LIO is transmitted onto the positive and the negative segment input/output lines SIO and /SIO and then to the positive and the negative bit lines BL and /BL. The data transmitted through the above path is finally stored in the memory cell 110.

FIG. 2 illustrates a waveform diagram for explaining operational waveforms of the positive and negative data lines transmitting the data in FIG. 1 and relates to the write operation.

As shown, in the write operation of the semiconductor memory device, the data is transmitted to the positive and the negative local input/output lines LIO and /LIO through the global input/output line GIO and then to the positive and the negative segment input/output lines SIO and /SIO through the positive and the negative local input/output lines LIO and /LIO.

In other words, data having a logic low level transmitted through the global input/output line GIO is transmitted to the positive segment input/output line SIO through the positive local input/output line LIO. At this time, if the negative local input/output line /LIO becomes to have a logic high level, the negative segment input/output line /SIO connected to the negative local input/output line /LIO also becomes to have a logic high level. Then, data having a logic high level transmitted through the global input/output line GIO is transmitted to the positive segment input/output line SIO through the positive local input/output line LIO. At this moment, the negative local input/output line /LIO and the negative segment input/output line /SIO become to have a logic low level.

As can be seen from FIGS. 1 and 2, the positive and the negative local input/output lines LIO and /LIO and the positive and the negative segment input/output lines SIO and /SIO construct a pair, respectively, and the input/output lines included in each pair have contrary logic levels.

Meanwhile, as a semiconductor memory device has been highly integrated, a design rule below a sub-micron scale is being applied to the design of internal circuits in the semiconductor memory device. Thus, a chip size of the semiconductor memory device becomes very small and an interval between data lines such as positive and negative local input/output lines LIO and /LIO and positive and negative segment input/output lines SIO and /SIO is also reduced. The reduction of the interval between the data lines makes the data lines more sensitive to a coupling effect.

Herein, the coupling effect means the influence of data transmitted through a certain data line on data transmitted through data lines adjacent to the certain data line. The coupling effect leads to the data loss or deteriorates the efficiency of a circuit operation by delaying a data transmission time.

FIG. 3A illustrates a view provided to explain the disposition of a plurality of conventional positive and negative local input/output lines. FIG. 3A shows first positive and negative local input/output lines LIO1 and /LIO1 and second positive and negative local input/output lines LIO2 and /LIO2 as examples.

As described above, the first positive and negative local input/output lines LIO1 and /LIO1 construct a pair and are disposed adjacent to each other and the second positive and negative local input/output lines LIO2 and /LIO2 also construct a pair and are disposed adjacent to each other. In case the first positive local input/output line LIO1 is coupled with a logic high level, the first negative local input/output line /LIO1 is coupled with a logic low level contrary to the logic high level. On the other hand, in case the first positive local input/output line LIO1 is coupled with a logic low level, the first negative local input/output line /LIO1 is coupled with a logic high level. This rule is also applied to the second positive and negative local input/output lines LIO2 and /LIO2.

FIG. 3B illustrates a view provided to explain data that could be provided to the first positive and negative local input/output lines LIO1 and /LIO1 and the second positive and negative local input/output lines LIO2 and /LIO2 described in FIG. 3A. In FIG. 3B, ‘1’ corresponds to a logic high level and ‘0’ corresponds to a logic low level.

Referring to FIG. 3B, since the first positive and negative local input/output lines LIO1 and /LIO1 are provided with different data values and the second positive and negative local input/output lines LIO2 and /LIO2 are also provided with different data values, the one-way coupling occurs in each of the pairs of positive and negative local input/output lines. However, the two-way coupling occurs in some cases. The first one of the cases where the two-way coupling occurs is that both the first positive local input/output line LIO1 and the second positive local input/output line LIO2 are provided with a logic low level. In this case, the two-way coupling occurs in the first negative local input/output line /LIO1. The second one of the cases where the two-way coupling occurs is that both the first positive local input/output line LIO1 and the second positive local input/output line LIO2 are provided with a logic high level. In this case, the two-way coupling occurs in the second positive local input/output line LIO2.

In the first case, the first negative local input/output line /LIO1 is driven with a core voltage having a precharge voltage level, and the first positive local input/output line LIO1 and the second positive local input/output line LIO2 are driven with a ground voltage. Considering the first negative local input/output line /LIO1 driven with the core voltage, the ground voltage driven to the first positive local input/output line LIO1 and the second positive local input/output line LIO2 leads to the loss of the core voltage of the first negative local input/output line /LIO1 or delays a time required in transmitting the data having the core voltage level. These problems also occur in the second case.

FIG. 4A illustrates a view provided to explain the disposition of a plurality of conventional positive and negative local input/output lines.

FIG. 4A shows first positive and negative local input/output lines LIO1 and /LIO1, second positive and negative local input/output lines LIO2 and /LIO2, third positive and negative local input/output lines LIO3 and /LIO3 and fourth positive and negative local input/output lines LIO4 and /LIO4 as examples.

As described above, the first positive and negative local input/output lines LIO1 and /LIO1 construct a pair and are disposed adjacent to each other; the second positive and negative local input/output lines LIO2 and /LIO2 also construct a pair and are disposed adjacent to each other; the third positive and negative local input/output lines LIO3 and /LIO3 also construct a pair and are disposed adjacent to each other; and the fourth positive and negative local input/output lines LIO4 and /LIO4 also construct a pair and are disposed adjacent to each other.

FIG. 4B illustrates a view provided to explain data that could be provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4 described in FIG. 4A. For the simplicity of explanation, FIG. 4B shows 4 cases.

As can be seen from FIG. 4B, the two-way coupling occurs at a larger number of parts than in FIG. 3B.

After all, there exist parts where the two-way coupling occurs in the plurality of positive and negative data lines disposed as shown in FIGS. 3A and 4B and the coupling causes the data loss or deteriorates the efficiency of a circuit operation by delaying the data transmission time.

### SUMMARY OF THE INVENTION

Embodiments of the present invention are directed to a semiconductor memory device capable of disposing any one of another positive and negative data lines between certain positive and negative data lines.

Moreover, there is provided a semiconductor memory device capable of disposing a plurality of positive data lines in a predetermined region and locating a region where a plurality of negative data lines are disposed to be adjacent to the predetermined region.

In accordance with an aspect of the present invention, there is provided a semiconductor memory device including: first positive and negative data lines driven with voltage levels contrary to each other in response to first data; and second positive and negative data lines driven with voltage levels contrary to each other in response to second data, wherein one of the second positive and negative data lines is disposed between the first positive and negative data lines.

In accordance with another aspect of the present invention, there is provided a semiconductor memory device including: a first region where first and second positive and negative data lines are disposed, wherein each of the first and the second positive and negative data lines are driven with voltage levels contrary to each other in response to a corresponding data and one of the second positive and negative data lines is disposed between the first positive and negative data lines; and a second region where third and fourth positive and negative data lines are disposed, wherein each of the third and the fourth positive and negative data lines are driven with voltage levels contrary to each other in response to a corresponding data and one of the fourth positive and negative data lines is disposed between the third positive and negative data lines, wherein the second region is adjacent to the first region.

In accordance with still another aspect of the present invention, there is provided a semiconductor memory device including a plurality of positive and negative data lines driven with voltage levels contrary to each other in response to a plurality of data, respectively, wherein a predetermined number of positive data lines are disposed in a first region and a predetermined number of negative data lines are disposed in a second region that is adjacent to the first region.

### BRIEF DESCRIPTION OF THE DRAWINGS

FIG. 1 is a diagram provided to explain read and write operations of a typical semiconductor memory device.

FIG. 2 illustrates a waveform diagram for explaining operational waveforms of positive and negative data lines transmitting data in FIG. 1.

FIGS. 3A and 4A illustrate diagrams provided to explain the disposition of a plurality of conventional positive and negative local input/output lines, respectively.

FIG. 3B illustrates a diagram provided to explain data that could be provided to first and second positive and negative local input/output lines described in FIG. 3A.

FIG. 4B illustrates a diagram provided to explain data that could be provided to first to fourth positive and negative local input/output described in FIG. 4A.

FIGS. 5A, 6A, 7A and 8A illustrate diagrams provided to explain the disposition of a plurality of positive and negative local input/output lines in accordance with embodiments of the present invention, respectively.

FIGS. 5B, 6B, 7B and 8B illustrate diagrams provided to explain data that could be provided to the plurality of positive and negative local input/output lines described in FIGS. 5A, 6A, 7A and 8A, respectively.

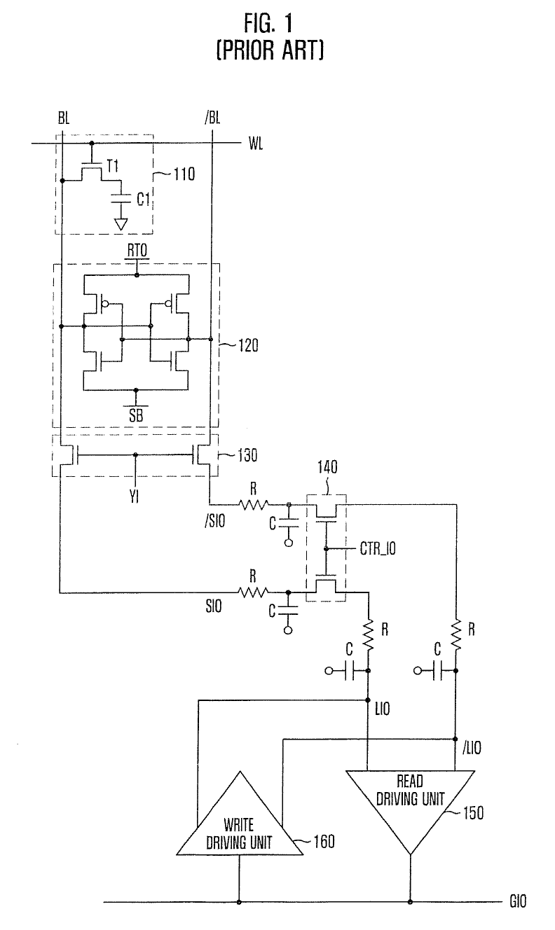

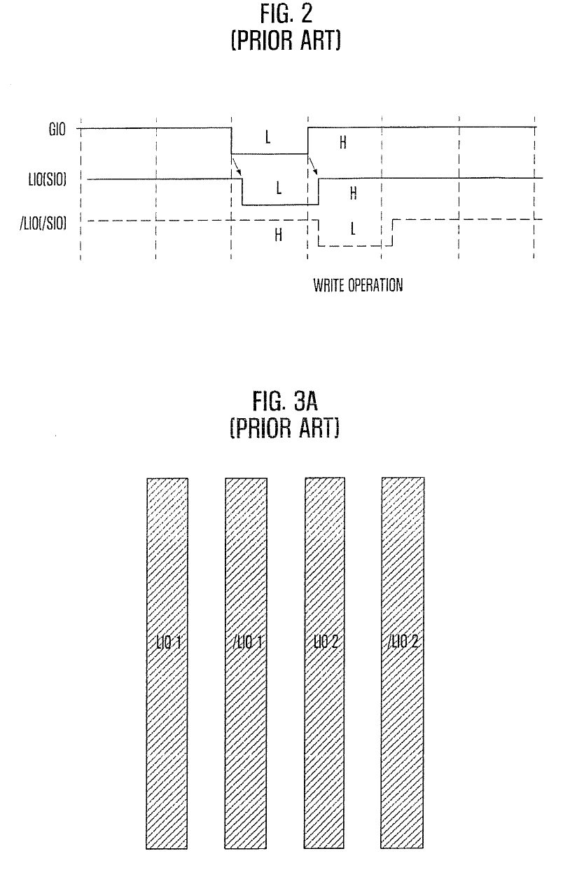

### DESCRIPTION OF SPECIFIC EMBODIMENTS

Other objects and advantages of the present invention can be understood by the following description, and become apparent with reference to the embodiments of the present invention.

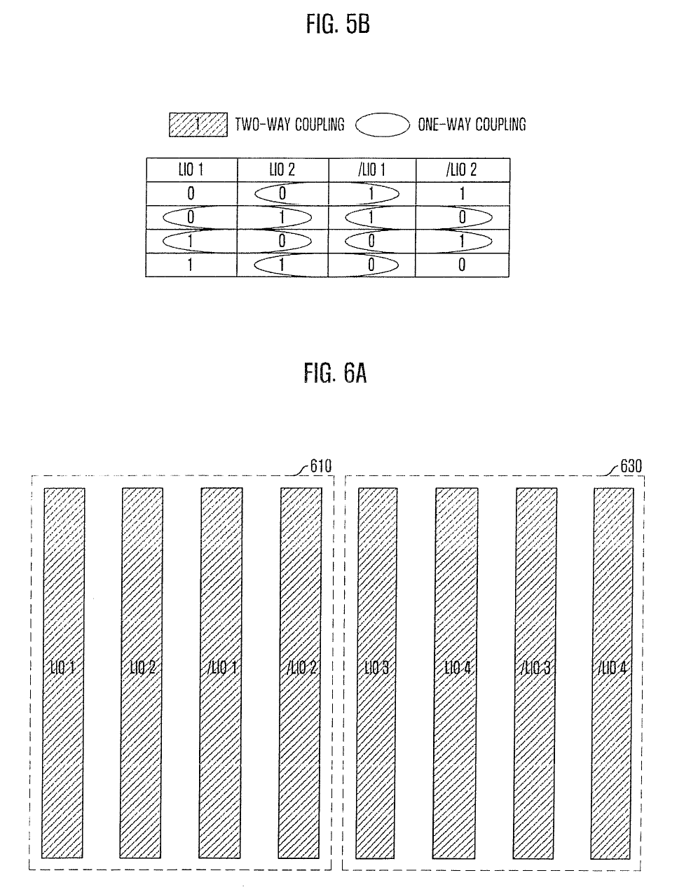

FIG. 5A illustrates a diagram for explaining the disposition of a plurality of positive and negative local input/output lines in a semiconductor memory device in accordance with an embodiment of the present invention and shows first positive and negative local input/output lines LIO1 and /LIO1 and second positive and negative local input/output lines LIO2 and /LIO2 as examples.

In the semiconductor memory device in accordance with this embodiment of the present invention, any one of second positive and negative data lines can be disposed between the first positive and negative data lines driven with contrary voltage levels according to data inputted to the semiconductor memory device. Herein, the first positive and negative data lines may correspond to the first positive and negative local input/output lines LIO1 and /LIO1 and the second positive and negative data lines may correspond to the second positive and negative local input/output lines LIO2 and /LIO2.

Then, the first positive and negative local input/output lines LIO1 and /LIO1 may be driven with contrary voltage levels according to data coupled thereto. That is, in case the first positive local input/output line LIO1 has a logic high level according to the data coupled thereto, the first negative local input/output line /LIO1 has a logic low level. On the other hand, in case the first positive local input/output line LIO1 has a logic low level according to the data coupled thereto, the first negative local input/output line /LIO1 has a logic high level. This rule can be applied to the second positive and negative local input/output lines LIO2 and /LIO2.

Referring to FIG. 5A, the second positive local input/output line LIO2 may be disposed between the first positive and negative local input/output lines LIO1 and /LIO1 and the first negative local input/output line /LIO1 may be disposed between the second positive and negative local input/output lines LIO2 and /LIO2. Herein, the first positive and negative local input/output lines LIO1 and /LIO1 may be disposed by replacing their locations with each other and the second positive and negative local input/output lines LIO2 and /LIO2 may be also disposed by replacing their locations with each other.

FIG. 5B illustrates a view provided to explain data that could be provided to the first positive and negative local input/output lines LIO1 and /LIO1 and the second positive and negative local input/output lines LIO2 and /LIO2 described in FIG. 5A. In FIG. 5B, ‘1’ corresponds to a logic high level and ‘0’ corresponds to a logic low level.

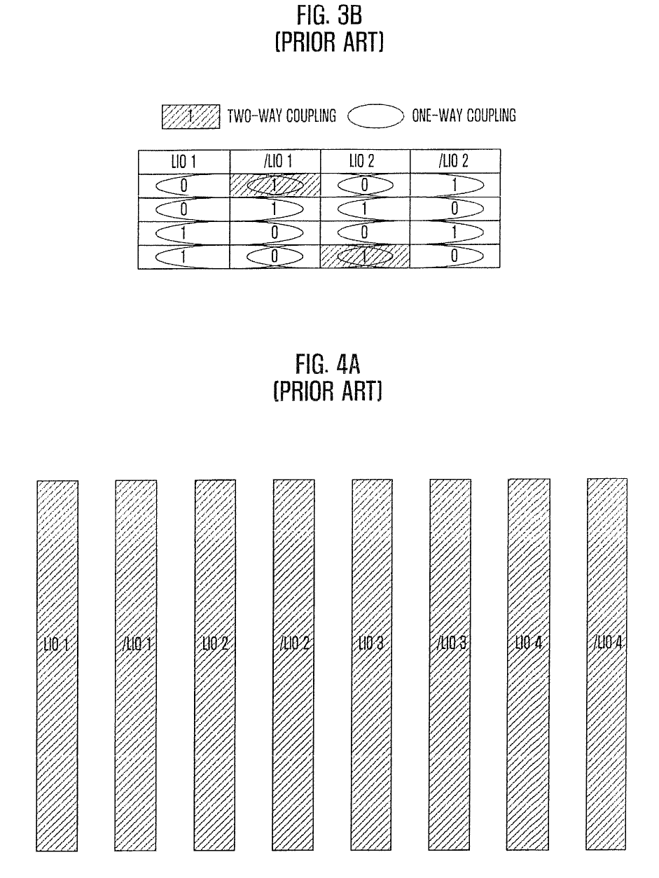

Referring to FIG. 5B, the first positive and negative local input/output lines LIO1 and /LIO1 are inputted with different data values and the second positive and negative local input/output lines LIO2 and /LIO2 are also inputted with different data values. Comparing FIG. 5B and FIG. 3B, it is noted that the two-way coupling that occurs in FIG. 3B disappears in FIG. 5B. The fact that the two-way coupling does not occur means that it is possible to transmit data without the data loss and the undesired delay.

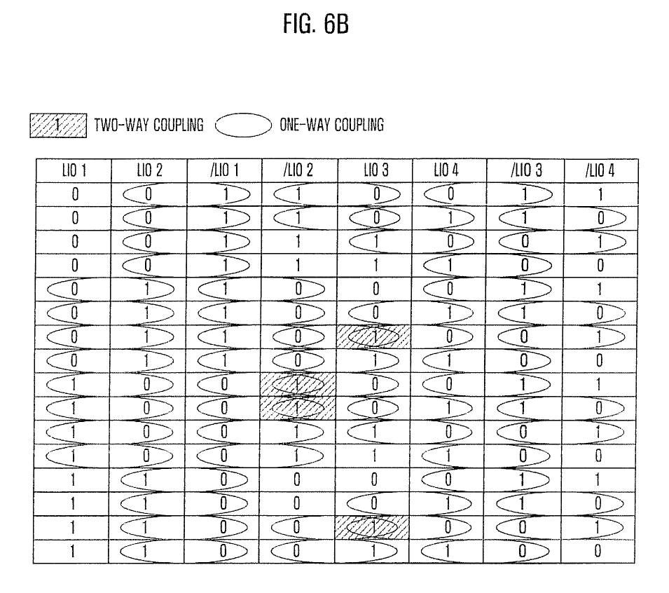

FIG. 6A illustrates a diagram for explaining the disposition of a plurality of positive and negative local input/output lines in accordance with an embodiment of the present invention and shows first positive and negative local input/output lines LIO1 and /LIO1, second positive and negative local input/output lines LIO2 and /LIO2, third positive and negative local input/output lines LIO3 and /LIO3 and fourth positive and negative local input/output lines LIO4 and /LIO4 as examples.

As shown, there are described a first region 610 where the first positive and negative local input/output lines LIO1 and /LIO1 and the second positive and negative local input/output lines LIO2 and /LIO2 are disposed and a second region 630 where the third positive and negative local input/output lines LIO3 and /LIO3 and the fourth positive and negative local input/output lines LIO4 and /LIO4 are disposed.

Herein, the disposition of each of the first region 610 and the second region 630 may correspond to the disposition described in FIG. 5A. In FIG. 6A, the first region 610 and the second region 630 may be disposed adjacent to each other.

FIG. 6B illustrates a diagram for explaining data that could be provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4 described in FIG. 6A.

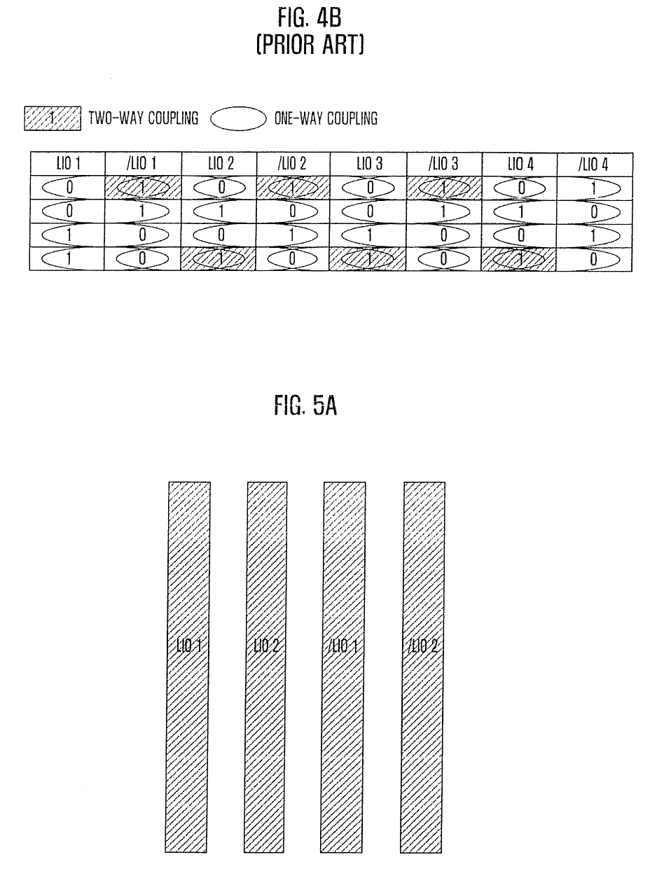

As can be seen from FIG. 6B, the two-way coupling occurs according to the data that could be provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4. However, comparing FIG. 6B and FIG. 4B, it is noted that the two-way coupling that occurs in FIG. 4B disappears in FIG. 6B. Although 4 numbers of two-way coupling occur according to the data that is provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4, it is noted that the occurrence of the two-way coupling is significantly reduced compared to the prior art.

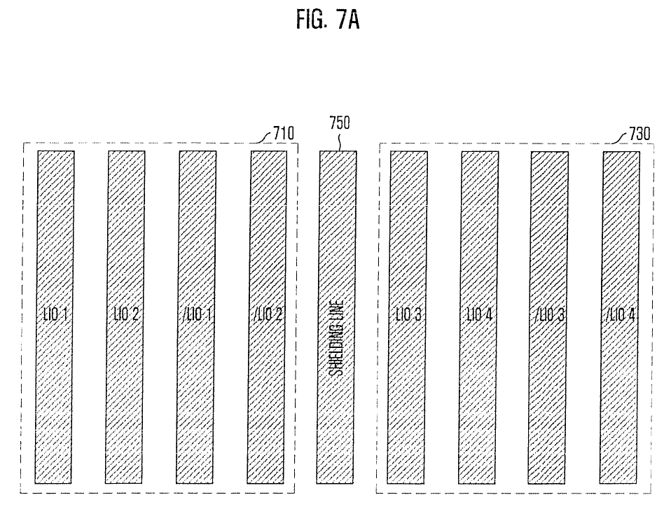

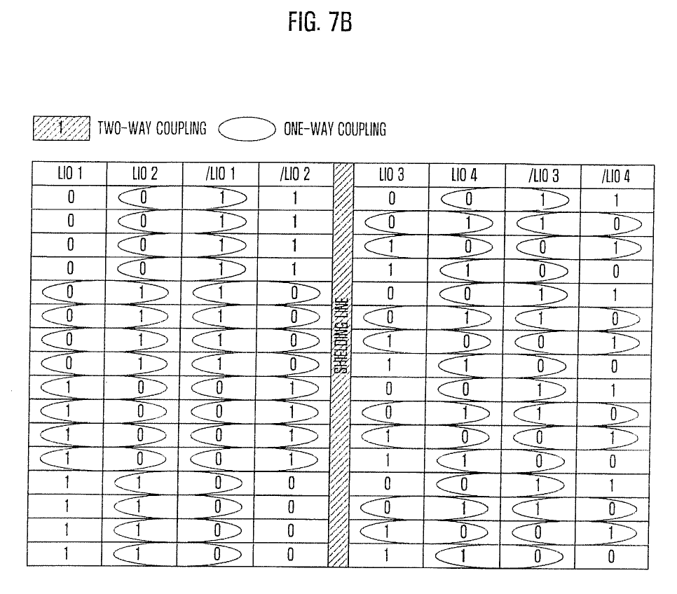

FIG. 7A illustrates the disposition of a plurality of positive and negative local input/output lines in accordance with an embodiment of the present invention and shows first positive and negative local input/output lines LIO1 and /LIO1, second positive and negative local input/output lines LIO2 and /LIO2, third positive and negative local input/output lines LIO3 and /LIO3 and fourth positive and negative local input/output lines LIO4 and /LIO4 as examples.

As shown, there are described a first region 710 where the first positive and negative local input/output lines LIO1 and /LIO1 and the second positive and negative local input/output lines LIO2 and /LIO2 are disposed, a second region 730 where the third positive and negative local input/output lines LIO3 and /LIO3 and the fourth positive and negative local input/output lines LIO4 and /LIO4 are disposed, and a shielding line 750.

Herein, the disposition of each of the first region 710 and the second region 730 may correspond to FIG. 5A. The shielding line 750 is disposed between the first region 710 and the second region 730. The shielding line 750 is a line where a predetermined voltage level can be coupled and thus may be a power line included in the semiconductor memory device or a line maintaining a constant voltage level corresponding to a logic low level or a logic high level.

FIG. 7B illustrates data that is provided to the first positive and negative local input/output lines LIO1 and /L100, the second positive and negative local input/output lines LIO2 and /LIO2, the third positive and negative local input/output lines LIO3 and /LIO3 and the fourth positive and negative local input/output lines LIO4 and /LIO4 described in FIG. 7A.

As can be seen from FIG. 7B, the two-way coupling does not occur in all cases of the data that is provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4. That is, the two-way coupling that occurs in FIG. 6B disappears in FIG. 7B by one shielding line.

Recently, as the number of lines disposed in the semiconductor memory device is increased, it is difficult to dispose a lot of shielding lines. In accordance with this embodiment of the present invention, it is possible to minimize the number of shielding lines in order to prevent the two-way coupling and thus to minimize the chip area of the semiconductor memory device.

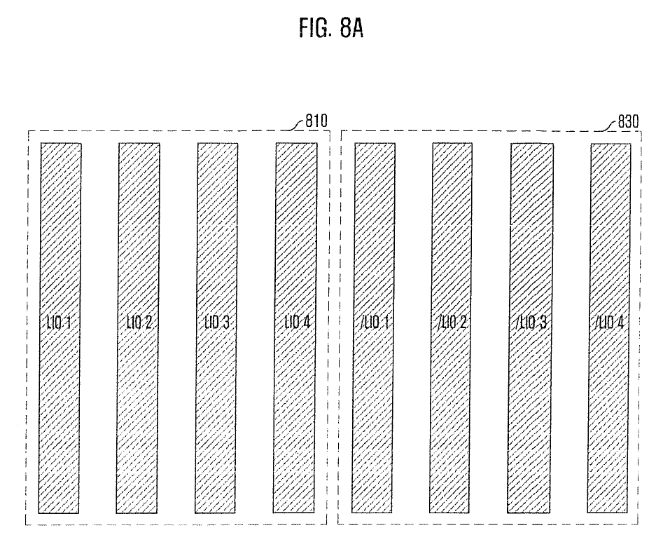

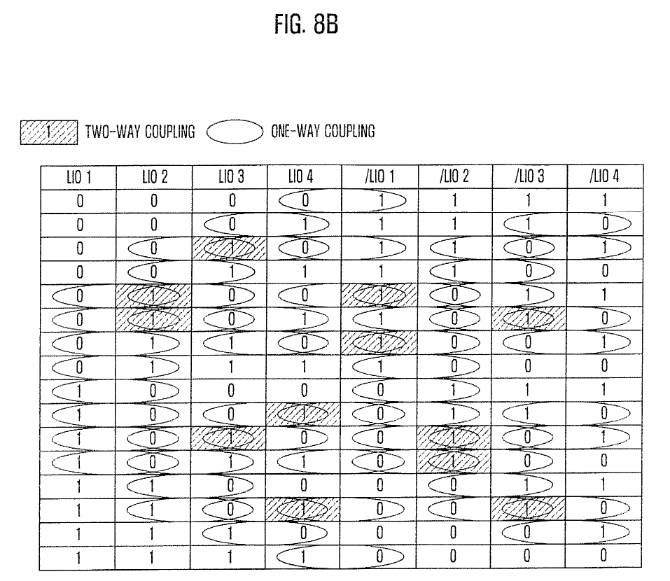

FIG. 8A illustrates a view provided to explain the disposition of a plurality of positive and negative local input/output lines in accordance with an embodiment of the present invention and shows first positive and negative local input/output lines LIO1 and /LIO1, second positive and negative local input/output lines LIO2 and /LIO2, third positive and negative local input/output lines LIO3 and /LIO3 and fourth positive and negative local input/output lines L104 and /LIO4 as examples.

Referring to FIG. 8A, there are described a positive line region 810 where the first to fourth positive local input/output lines LIO1, LIO2, LIO3 and LIO4 are disposed and a negative line region 830 where the first to the fourth negative local input/output lines /LIO1, /LIO2, /LIO3 and /LIO4 are disposed. In other words, among a plurality of positive and negative local input/output lines, a plurality of lines corresponding to the positive local input/output lines and a plurality of lines corresponding to the negative local input/output lines are disposed separately.

Herein, the positive line region 810 and the negative line region 830 may be disposed adjacent to each other and such a shielding line as described in FIG. 7A may be disposed between the positive line region 810 and the negative line region 830. Furthermore, the positive line region 810 may include at least one shielding line disposed parallel to the positive local input/output lines and the negative line region 830 may also include at least one shielding line disposed parallel to the negative local input/output lines. In FIG. 8B, the shielding line is not described and not considered.

FIG. 8B illustrates a view provided to explain data that could be provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4 described in FIG. 8A.

As can be seen from FIG. 8B, although the two-way coupling occurs according to the data that is provided to the first positive and negative local input/output lines LIO1 and /LIO1, the second positive and negative local input/output lines LIO2 and /LIO2, the third positive and negative local input/output lines LIO3 and /LIO3 and the fourth positive and negative local input/output lines LIO4 and /LIO4, it is noted that the occurrence of the two-way coupling is significantly reduced compared to the prior art.

As describe above, in accordance with the present invention, it is possible to minimize the occurrence of the coupling by disposing any one of positive and negative data lines included in another pair of data lines between positive and negative data lines included in a certain pair of data lines, or disposing a plurality of positive data lines in a predetermined region and locating a region where a plurality of negative data lines are disposed to be adjacent to the predetermined region. The minimization of the coupling can prevent the data loss and minimize the data transmission time.

Moreover, in accordance with the present invention, since the occurrence of the coupling can be minimized by using a minimized number of shielding lines, it is possible to decrease the chip area of the semiconductor memory device, so that the cost of production of the semiconductor memory device is reduced and the competitiveness of the semiconductor memory device is strengthened.

While the present invention has been described with respect to the specific embodiments, it will be apparent to those skilled in the art that various changes and modifications may be made without departing from the spirit and scope of the invention as defined in the following claims.

Although the above embodiments of the present invention are illustrated with respect to the local input/output lines, the present invention is applicable to the segment input/output lines and further to all data lines transferring positive and negative data according to data coupled thereto.

What is claimed is:

1. A semiconductor memory device, comprising:
first positive and negative data lines driven with voltage levels contrary to each other in response to first data; and
second positive and negative data lines driven with voltage levels contrary to each other in response to second data,
wherein one of the second positive and negative data lines is disposed between the first positive and negative data lines.

2. The semiconductor memory device of claim 1, wherein the first and second positive and negative data lines are local input/output lines or segment input/output lines.

3. A semiconductor memory device, comprising:
a first region where first and second positive and negative data lines are disposed, wherein each of the first and the second positive and negative data lines are driven with voltage levels contrary to each other in response to a corresponding data and one of the second positive and negative data lines is disposed between the first positive and negative data lines; and
a second region where third and fourth positive and negative data lines are disposed, wherein each of the third and the fourth positive and negative data lines are driven with voltage levels contrary to each other in response to a corresponding data and one of the fourth positive and negative data lines is disposed between the third positive and negative data lines, wherein the second region is adjacent to the first region.

4. The semiconductor memory device of claim 3, further comprising a shielding line disposed between the first region and the second region.

5. The semiconductor memory device of claim 4, wherein the shielding line is coupled with a predetermined voltage level.

6. The semiconductor memory device of claim 3, wherein the first to fourth positive and negative data lines are local input/output lines or segment input/output lines.

7. A semiconductor memory device, comprising:
a plurality of positive and negative data lines driven with voltage levels contrary to each other in response to a plurality of data, respectively, wherein a predetermined number of positive data lines are disposed in a first region and a predetermined number of negative data lines are disposed in a second region that is adjacent to the first region.

8. The semiconductor memory device of claim 7, further comprising a first shielding line disposed between the first region and the second region.

9. The semiconductor memory device of claim 7, further comprising at least one second shielding line disposed parallel to the positive data lines in the first region.

10. The semiconductor memory device of claim 7, further comprising at least one third shielding line disposed parallel to the negative data lines in the second region.

11. The semiconductor memory device of claim 8, wherein the first shielding line is coupled with a predetermined voltage level.

12. The semiconductor memory device of claim 7, wherein the plurality of positive and negative data lines are local input/output lines or segment input/output lines.
